(19) United States
(12) Patent Application Publication
(10) Pub. No.: US 2006/0088988 A1
(43) Pub. Date: Apr. 27, 2006

(54) Method for forming silicon-germanium in the upper portion of a silicon substrate

(75) Inventors: Aomar Halimaoui, La Terrasse (FR); Frederic Boeuf, Le Versoud (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics CROLLES 2 SAS, Crolles (FR)

(21) Appl. No.: 11/258,402

(22) Filed: Oct. 25, 2005

(30) Foreign Application Priority Data
Oct. 25, 2004 (FR) 04/52432

(51) Int. Cl. H01L 21/04

(52) U.S. Cl. 438/510

(57) ABSTRACT

A method for forming silicon-germanium in the upper portion of a silicon substrate, including the steps of: depositing a germanium layer doped at a concentration in dopant elements greater than 10¹⁹ atoms per cm³ on a silicon substrate; heating to have the germanium diffuse into the silicon substrate to form a doped silicon-germanium layer in the upper portion of the silicon substrate; and eliminating the germanium layer.

### BACKGROUND OF THE INVENTION

1. Field of the Invention

The present invention relates to a method for forming a silicon-germanium layer or region in the upper portion of a silicon substrate and a specific application of this method to the forming of a MOS transistor.

2. Discussion of the Related Art

FIG. 1 is a cross-section view of a PMOS transistor comprising silicon-germanium areas at the level of its source and drain regions. In a silicon substrate 1, an insulation area 2 delimits an active area 3. A gate 4 comprising a thin oxide, a polysilicon layer, and insulating spacers on the side is placed above the central portion of active area 3. Source and drain silicon-germanium areas 5 and 6 are placed in the upper portion of active area 3 on either side of gate 4.

The presence of silicon-germanium 5 and 6 on each side of the channel area of the PMOS transistor results in exerting mechanical stress on this channel area. This mechanical stress increases the mobility of the channel carriers and accordingly increases the current flowing through the transistor and its switching rapidity.

A conventional method for forming silicon-germanium areas 5 and 6 is the following.

In an initial step, illustrated in FIG. 2A, an insulation area 11 delimiting an active area 12 is formed at the surface of a silicon substrate 10. A transistor gate 13 is then formed above the central area of active area 12.

The silicon portions which are desired to be replaced with silicon-germanium are then etched. In this example, openings t1 and t2 are formed in active area 12 on either side of gate 13.

Then, as illustrated in FIG. 2B, silicon-germanium portions 20 and 21 are grown by epitaxy in openings t1 and t2. This epitaxy is performed according to a standard vapor deposition at high temperature, typically between 400° C. and 800° C., from a gas mixture of silicon and germanium precursors such as silane SiH₄ and germane GeH₄.

A disadvantage of this method is that it is necessary to cover gate 13 with a protection layer so that the polysilicon layer of the gate is not etched on forming of openings t1 and t2. Although the silicon can be etched selectively with respect to the insulating materials, the etching is never selective and the protection layer must be provided to be sufficiently thick. Now, the use of a thick protection layer is a disadvantage on forming of gate 13. Conventionally, to form gate 13, an oxide layer, a polysilicon layer, and a protection layer for example, silicon oxide, are deposited on the substrate, after which each of the layers is etched. Now, the thicker the gate, the more difficult it is to obtain a gate of small width. Indeed, etchings are never perfectly anisotropic and a high and narrow gate would risk to “fall”.

Further, a problem inherent to silicon substrate etching methods is that the depth of the formed openings varies according to the surface area of the openings and to the density of openings on a given area of the substrate. The depth of an opening is all the smaller as its surface area is large or as the number of neighboring openings is high. Although the epitaxial growth speed of silicon-germanium areas is generally all the faster as the density of openings is small, it is not possible in practice to obtain a perfect compensation.

Another disadvantage of this method is that, even by using a selective epitaxial growth method, a thin silicon-germanium layer tends to grow above the insulating areas, especially above the spacers and above the insulation areas separating the active areas. This thin silicon-germanium layer is likely to create short-circuits between components and must thus be eliminated by etching. Now, on etching, silicon-germanium areas 20 and 21 are also partially etched.

Generally, conventional methods of silicon-germanium forming on or in silicon are epitaxial growth methods, which causes the above-mentioned disadvantages in the case of a specific application.

European patent application 0 613 175 describes a method for making a MOS transistor on a silicon substrate. During the doping stage for forming source/drain areas, a germanium layer doped with boron is formed on the substrate and during subsequent annealing the germanium and the boron diffuse in the substrate. During this diffusion, a thin layer of doped silicon-germanium is formed. Finally, this silicon-germanium layer is removed.

A disadvantage of this method for making silicon-germanium is that the duration of the high temperature annealing process necessary for the germanium diffusion becomes prohibitive when forming a thick layer of silicon-germanium. Furthermore, prolonged annealing results in the undesired diffusion of other doped areas previously formed in the substrate.

### SUMMARY OF THE INVENTION

Thus, a general object of the present invention is to provide a method for making thick layers of silicon-germanium forming at the surface of a silicon substrate without prohibitive prolonged annealing.

Another object of the present invention is to provide such a method which enables obtaining silicon-germanium portions of identical thickness whatever their surface areas.

Another object of the present invention is to provide such a method which is easy to implement.

Another object of the present invention is to provide such a method which is well adapted to the forming of MOS transistor source and drain areas.

To achieve these and other objects, the present invention provides a method for forming silicon-germanium in the upper portion of a silicon substrate comprising the steps of: performing an implantation of heavy ions in a silicon substrate to form crystal defects in an upper portion of the substrate; depositing a germanium layer doped at a concentration in dopant elements greater than 10¹⁹ atoms per cm³ on the silicon substrate; heating to have the germanium diffuse into the silicon substrate to form a doped silicon-germanium layer in the upper portion of the silicon substrate; and eliminating the germanium layer.

According to a variation of the previously-described method, the doping element of the germanium layer is boron.

According to a variation of the previously-described method, the boron concentration ranges between 10²⁰ and 10²² atoms/cm³.

According to a variation of the previously-described method, the heating step is performed at a temperature ranging between 700 and 900° C., and preferably between 800 and 900° C.

According to a variation of the previously-described method, insulation areas are formed in the silicon substrate prior to the deposition of a doped germanium layer, the insulation areas delimiting active areas on which said germanium layer is deposited.

The present invention also provides a method for forming a PMOS transistor, comprising the steps of: forming, at the surface of a silicon substrate, an insulation area surrounding an N-type doped active area; forming a transistor gate comprising an oxide layer, a polysilicon layer, insulating spacers on the sides of the gate, and possibly a protection layer; and performing the steps of the previously-described method to form at the surface of the active area silicon-germanium source and drain areas doped with boron on either side of the gate.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1 is a cross-section view, previously described, of a MOS transistor with a stressed channel;

FIGS. 2A and 2B are cross-section views of structures obtained after successive steps of implementation of a silicon-germanium forming method, previously described;

FIGS. 3A to 3C are cross-section views of structures obtained after successive steps of implementation of a method according to the present invention of silicon-germanium forming in an upper portion of a silicon substrate; and

FIGS. 4A to 4D are cross-section views of structures obtained after successive steps of a method for forming a PMOS transistor according to the present invention.

### DETAILED DESCRIPTION

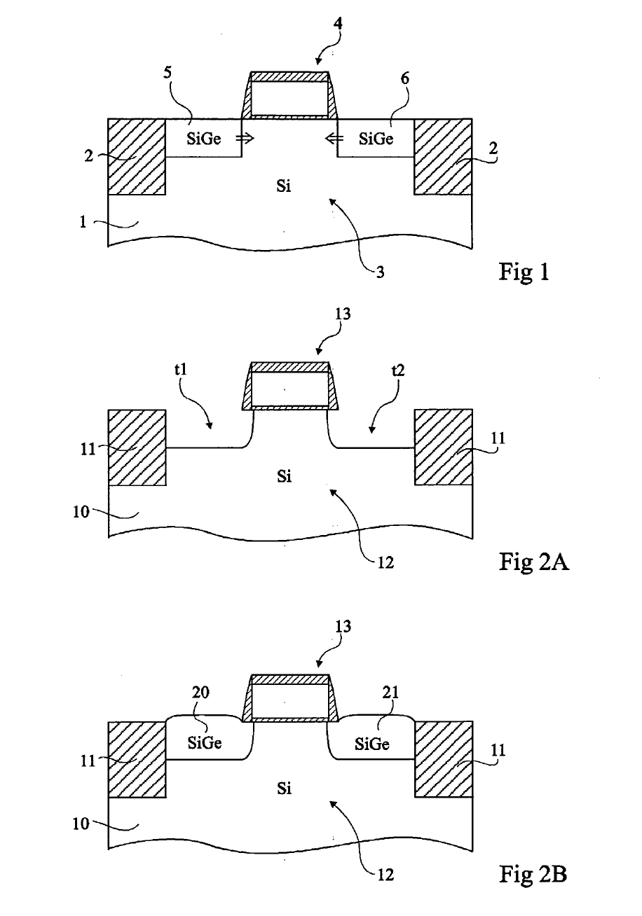

For clarity, the same elements have been designated with the same reference numerals in the different drawings and, further, as usual in the representation of integrated circuits, FIGS. 1, 2, 3 and 4 are not drawn to scale.

The method of the present invention aims at forming silicon-germanium in the upper portion of a silicon substrate. This method is particularly well adapted to the forming of multiple silicon-germanium portions at the surface of active areas previously defined in a silicon substrate.

The method of the present invention enables diffusing germanium in a silicon substrate from a doped germanium layer previously deposited on the silicon substrate. According to an aspect of the present invention, heavy ions are implanted in the upper portion of the substrate before the germanium layer is deposited in order to enhance and accelerate the diffusion of germanium in the substrate.

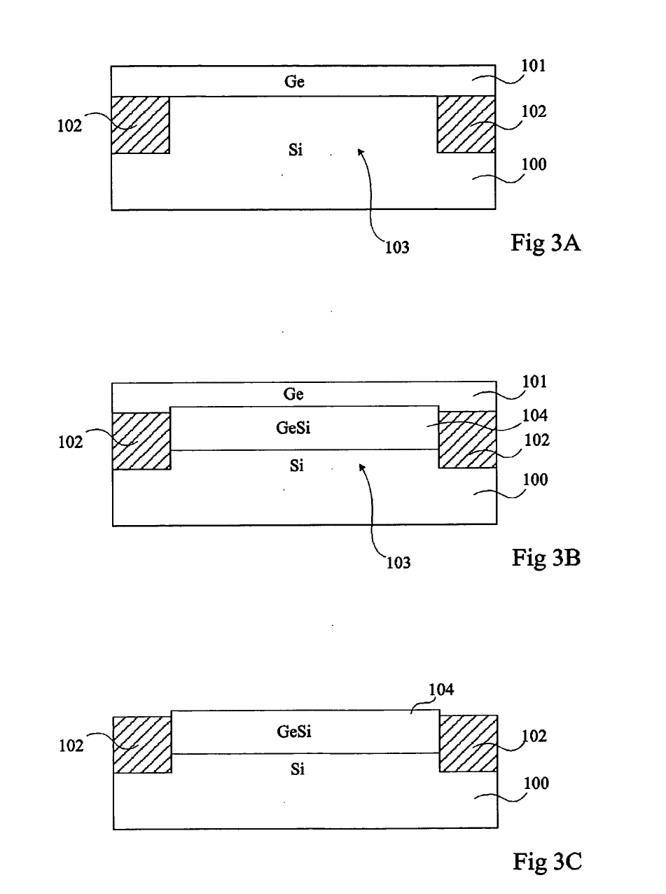

An embodiment of the method of the present invention is described in more detail hereafter in relation with FIGS. 3A to 3C.

In an initial step, illustrated in FIG. 3A, heavy ions are implanted in a silicon substrate substrate 100. Then, a germanium layer 101 containing boron is formed on the silicon substrate 100. Germanium layer 101 may be formed according to a standard vapor deposition method performed at a temperature of approximately 350° C. from a gas mixture of germane GeH₄ and a precursor of boron B such as diborane B₂H₆. In this example, an insulation area 102 surrounds an active area 103 at the surface of which a silicon-germanium area is desired to be formed.

At the next step, illustrated in FIG. 3B, the previously-obtained structure is placed in an enclosure at a temperature between 700 and 900° C. The germanium then diffuses into silicon substrate 100 to form a silicon-germanium layer 104 in the upper portion of silicon layer 100, at the surface of active area 103 in this example. The silicon-germanium layer 104 thus obtained contains the dopant element initially present in doped germanium layer 101. At the end of this germanium diffusion, germanium layer 101 has more or less thinned down according to whether the formed silicon-germanium layer 104 is thicker or thinner.

At the next step, illustrated in FIG. 3C, germanium layer 101 is eliminated by selective etch.

According to an aspect of the present invention, the heavy ion implantation enables creating crystal defects in active area 103. The crystal defects thus formed accelerate the germanium diffusion in silicon substrate 100. The crystal defects are then naturally eliminated in subsequent method steps providing an anneal. Various types of heavy ions may be implanted. Silicon or germanium ions may for, example, be implanted. These ions have the advantage of not modifying the local doping of the substrate and of being integrated in the finally-formed silicon-germanium layer.

For the same temperature and anneal time, the presence of crystal defects enables doubling or tripling the diffusion depth of germanium in the active area 103.

The diffusion depth becomes greater as the concentration of dopant elements in the germanium layer increases. The germanium diffusion in the silicon is negligible for dopant element concentrations smaller than 10¹⁹ atoms/cm³. The germanium reaches a depth smaller than a few atomic layers when the dopant element concentration exceeds 10¹⁹ atoms/cm³. When the concentration exceeds 10²⁰ atoms/cm³, really significant diffusion depths greater than a few tens of nanometers are obtained. For concentrations in the order of 10²¹ to 10²² atoms/cm³, the diffusion depth can reach several hundred nanometers.

The above-specified diffusion depths correspond to a method in which annealing is performed at approximately 850° C. for a few minutes. The heavy ion implantation dose is about 10¹⁵ ions/cm². The diffusion depth may however increase or decrease by increasing or decreasing the annealing temperature or duration. It should however be noted that the element that enables the germanium diffusion to start and catalyze is the presence of a dopant element such as boron in the germanium layer. Without the presence of dopant elements, several hours, or even several days would be necessary to form a thin silicon-germanium layer.

A particularly advantageous application of the method of the present invention is the forming of a PMOS transistor with a stressed channel such as that shown in FIG. 1.

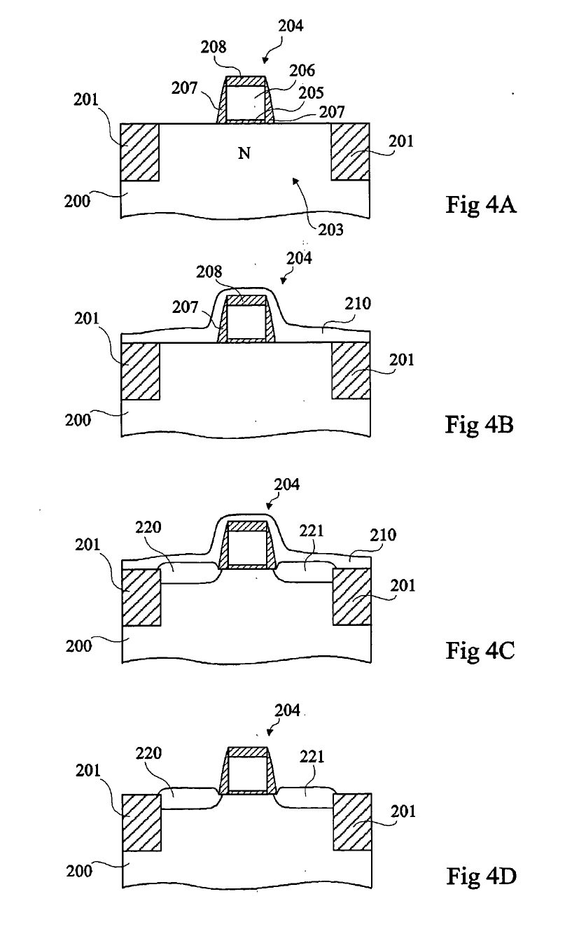

In an initial step, illustrated in FIG. 4A, an insulation area 201 surrounding an active area 203 doped with an N-type dopant element is formed in a silicon substrate 200. A transistor gate 204 comprising a gate oxide 205, a polysilicon layer 206, and insulating spacers 207 on the sides of the gate are then conventionally formed. A protection layer 208 covers gate 204.

At the next step, illustrated in FIG. 4B, heavy ions are implanted in the non-covered areas of active area 203 and a germanium layer 210 doped with a P-type dopant element such as boron is deposited over the entire structure. The germanium deposition may be performed according to a conventional vapor deposition method performed from germane GeH₄ and a boron precursor such as diborane B₂H₆. This deposition method is naturally selective, the germanium depositing easily on the silicon areas, and uneasily on insulating areas such as insulation area 201, spacers 207, and protection layer 206.

At the next step, illustrated in FIG. 4C, the structure is placed in an enclosure at a temperature ranging between 800 and 900° C. The germanium diffuses in the silicon on either side of gate 204 to form silicon-germanium areas forming heavily-doped P-type source and drain areas 220 and 221.

At the next step, illustrated in FIG. 4D, germanium layer 210 is eliminated.

In this method, the function of protection layer 208 covering gate 204 is to avoid for germanium to diffuse into the gate. This protection layer may be a very thin silicon oxide layer conversely to that used in the conventional method described in relation with FIGS. 2A and 2B. Further, in the method of the present invention, it would be possible not to provide protection layer 208 if the gate is thick enough for the germanium not to diffuse down to gate oxide 205.

An advantage of the method of the present invention thus is that the protection layer covering the gate of a transistor may be very thin, or even non-existent, which finally provides narrower transistor gates.

Another advantage of the previously-described method is that the thickness of source and drain areas 220 and 221 is constant whatever the surface of these areas.

Another advantage of the previously-described method is that during the PMOS transistor forming method according to the present invention, no silicon-germanium layer forms on insulation areas 201 or on spacers 207. No step of cleaning of the insulating areas likely to etch the source-drain silicon-germanium layers is then necessary.

Of course, the present invention is likely to have various alterations, modifications, and improvements which will readily occur to those skilled in the art. In particular, the method of the present invention may be implemented on any type of structure comprising a silicon area at the surface of which a doped silicon-germanium layer is desired to be formed. Further, the method of the present invention may be used to form other components. More generally, this method may be used to form heavily-doped areas in the upper portion of a silicon substrate, noting that dopants other than boron, for example, arsenic or phosphorus, may be used.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for forming silicon-germanium in the upper portion of a silicon substrate, comprising:
performing an implantation of heavy ions in a silicon substrate to form crystal defects in an upper portion of the substrate;
depositing a germanium layer doped at a concentration in dopant elements greater than 10¹⁹ atoms per cm³ on the silicon substrate;
heating to have the germanium diffuse into the silicon substrate to form a doped silicon-germanium layer in the upper portion of the silicon substrate; and
eliminating the germanium layer.

2. The method of claim 1, wherein the doping element of the germanium layer is boron.

3. The method of claim 2, wherein the boron concentration ranges between 10²⁰ and 10²² atoms/cm³.

4. The method of claim 1, wherein the heating step is performed at a temperature ranging between 700 and 900° C., and preferably between 800 and 900° C.

5. The method of claim 1, wherein insulation areas are formed in the silicon substrate prior to the deposition of a doped germanium layer, the insulation areas delimiting active areas on which said germanium layer is deposited.

6. A method for forming a PMOS transistor comprising:
forming, at the surface of a silicon substrate, an insulation area surrounding an N-type doped active area;
forming a transistor gate comprising an oxide layer, a polysilicon layer, insulating spacers on the sides of the gate, and possibly a protection layer; and
performing the steps of the method of claim 2 to form, at the surface of the active area, silicon-germanium source and drain areas doped with boron on either side of the gate.
